(19) United States
(12) Patent Application Publication
(10) Pub. No.: US 2022/0399891 A1
(43) Pub. Date: Dec. 15, 2022

(54) CONTACTLESS BUTTON STRUCTURE

(71) Applicant: HTGOLD International Corp., Taoyuan (TW)

(72) Inventor: Meng-Chang HO, Taoyuan (TW)

(21) Appl. No.: 17/829,833

(22) Filed: Jun. 1, 2022

(30) Foreign Application Priority Data
Jun. 9, 2021 (TW) 110206673

(51) Int. Cl. H03K 17/945

(52) U.S. Cl. CPC H03K 17/945

(57) ABSTRACT

A contactless button structure includes a frame body with indicating key surfaces on one side thereof and an isolation space on an opposite side thereof, and a driving unit installed in the isolation space. The driving unit includes a plurality of sensing devices respectively installed on the back side of each indicating key surface and a control unit that receives the electronic signal of each sensing device. The control unit includes a plurality of trigger devices corresponding to the sensing devices respectively. Each trigger device has a retractable trigger rod. The contactless button structure can be installed outside the control key surface of the equipment (such as elevators, etc.) in the building, and the user's finger can approach any indicating key surface of the frame body of the button structure to achieve the purpose of non-contact touch control buttons. it can protect against contact infectious germs,

This application claims the priority benefit of Taiwan patent application number 110206673, filed on Jun. 9, 2021.

### BACKGROUND OF THE INVENTION

### 1. Field of the Invention:

The present invention provides a contactless button. structure, especially a button structure for performing touch button operation by means of induction, wherein one side of the frame body is provided with plural indicating key surfaces, and the isolation space on the other side of the frame body is provided with plural sensing devices and a control unit of a driving unit. Through the control unit, multiple trigger devices can be used to touch the corresponding touch buttons to achieve the purpose of non-contact operation of the touch buttons.

### 2. Description of the Related Art:

In the elevators in various buildings, there are quite a lot of people entering and leaving every day. In the elevator, the keypad. surface for selecting floors and opening and closing doors has also become a tool that must be contacted by people entering and leaving. Of course, people are inevitably exposed to viruses or bacteria in their daily lives. Especially when the epidemic of infectious diseases spreads, various viruses, bacteria, etc are more likely to be spread through human contact, and people are vulnerable to the disease if they are not careful. The elevators where people often go in and out are also confined spaces, and there are many people entering and exiting. The number of times that the keypads of the elevators for selecting floors are difficult to count every day, and therefore it is easy to become one of the ways of spreading the disease. In the environment where most unspecified people enter and exit such as medical institutions and. public places, the number of people using elevators is quite complicated, and the number of elevators is used more frequently, which will be more serious for the spread of epidemics. Therefore, during the epidemic period, the disinfection of elevators in various living environments and public places is also more important. However, the current disinfection in the elevator is all about spraying the disinfectant, and sticking the adhesive film on the keypad surface of the selected floor to wipe the disinfectant and other disinfection operations. However, it is easy to reduce the efficacy of the disinfectant solution and increase the chance of the spread of viruses, bacteria after a period of time. Therefore, elevators in various buildings must be disinfected several times a. day. In addition, the access control man-machine interface, walkie-talkie, etc. of each building are also the equipment that people entering and leaving come into contact with every day. They all have numeric keys, switch keys or contact keys for pressing, and people entering and leaving will touch and press them, and they must also be disinfected regularly or irregularly. Therefore, all kinds of buildings disinfect elevators, access control man-machine interfaces or walkie-talkies every day. In addition to increasing the cost of disinfection operations, it is also time-consuming and labor-intensive for the staff.

### SUMMARY OF THE INVENTION

The present invention has been accomplished under the circumstances in view. It is therefore the main object of the present invention to a contactless button structure, which comprises a frame body with indicating key surfaces on one side thereof and an isolation space on an opposite side thereof, and a driving unit installed in the isolation space. The driving unit comprises a plurality of sensing devices respectively installed on the back side of each indicating key surface, and a control unit that receives the electronic signal of each sensing device. The control unit comprises a plurality of trigger devices corresponding to the sensing devices respectively. Each trigger device has a retractable trigger rod. The contactless button structure can be installed outside the control key surface of the equipment (such as elevators, access control man-machine interfaces or walkie-talkies, etc.) in the building, and the user's finger can approach any indicating key surface of the frame body of the button structure to achieve the purpose of non-contact touch control buttons. It can prevent the function of contact infectious bacteria, and can also reduce the risk of disease transmission and spread.

It is another object of the present invention to a contactless button structure, wherein the plural indicating key surfaces of the frame body comprise a plurality of number keys and moving direction keys and a contact mark key respectively marked with a respective symbol.

It is another object of the present invention to a contactless button structure, wherein the sensing devices of the driving unit can be temperature sensors or infrared sensors, and the control unit of the driving unit is a circuit board with an electronic circuit layout. The circuit board of the control unit can be provided with a power supply for supplying the required electrical energy. The power supply can be general batteries, lithium batteries, rechargeable batteries, accumulators or commercial power and other types of power sources that can provide electrical energy. The control unit comprises a plurality of signal transceivers. The sensing devices respectively comprise a signal transmitter for signal transmission with one respective signal transceiver. The signal transmission between the signal transceivers of the control unit and the signal transmitters of the sensing devices can be carried out by wired or wireless means, Each trigger device of the driving unit can be a motor, a pneumatic cylinder, a hydraulic cylinder or an electric cylinder,

### BRIEF DESCRIPTION OF THE DRAWINGS

FIG. 1 is an oblique front elevational view of a contactless button structure in accordance with the present invention.

FIG. 2 is an oblique rear elevational view of the contactless button structure in accordance with the present invention.

FIG. 3 is a block diagram of the contactless button structure in accordance with the present invention.

FIG. 4 is a perspective view of an implemented embodiment of the present invention.

FIG. 5 is a partial side sectional view (I) of the implemented embodiment of the present invention,

FIG. 6 is a partial side sectional view (II) of the implemented embodiment of the present invention.

FIG. 7 is an oblique front devotional view of another implemented embodiment of the present invention.

FIG. 8 is a side sectional view before application of another implemented embodiment of the present invention,

FIG. 9 is a side sectional view of another implemented. embodiment of the present invention when applied.

### DETAILED DESCRIPTION OF THE PREFERRED EMBODIMENT

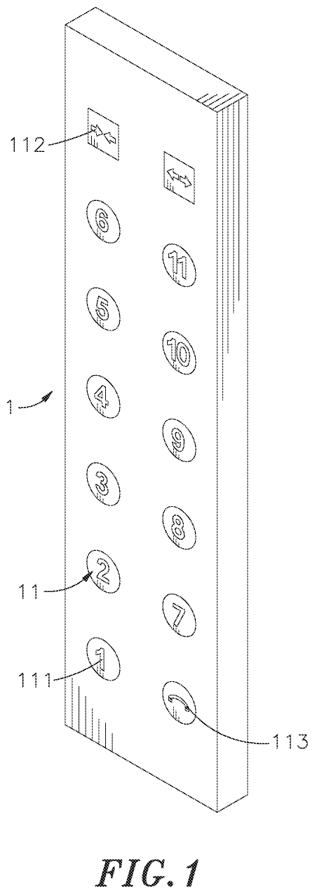

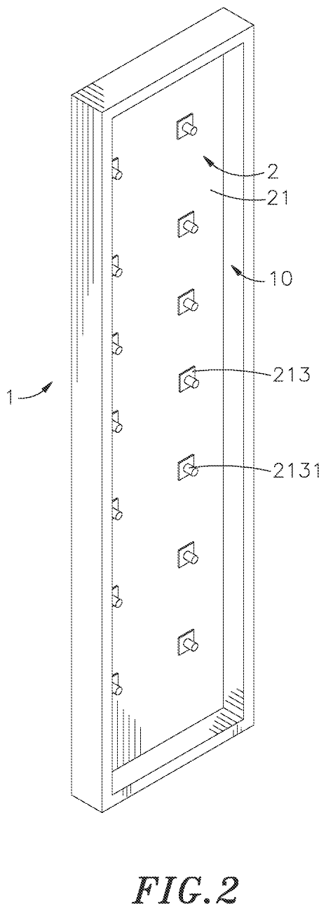

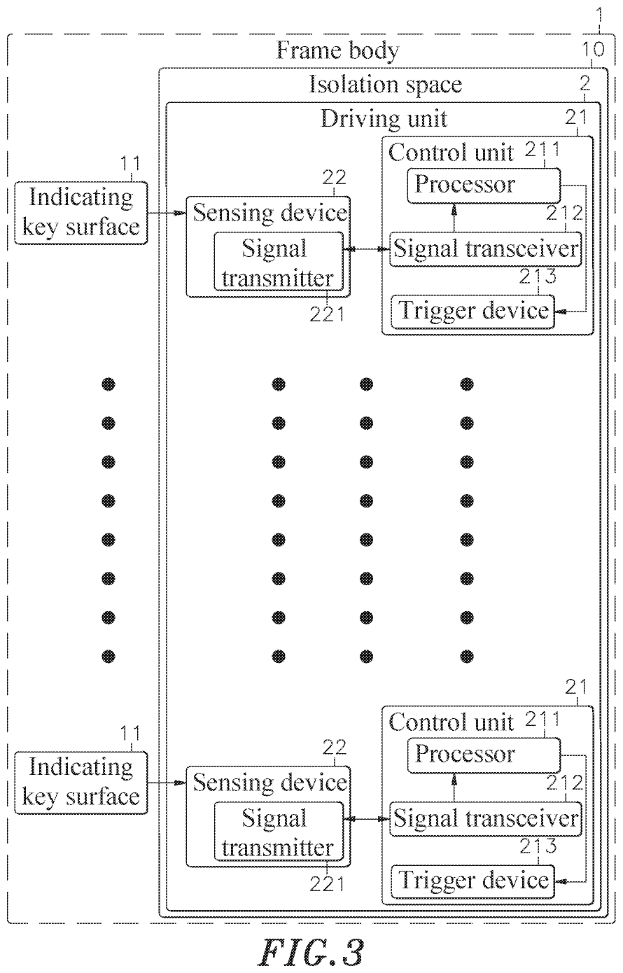

Referring to FIGS. 1-3, as can be clearly seen from the drawings, the contactless button structure of the present invention comprises a frame body 1 and a driving unit 2.

The frame body 1 is provided with a plurality of indicating key surfaces 11 on one side, and an isolation space 10 is concavely provided on the other side.

The driving unit 2 comprises a control unit 21, and a plurality of sensing devices 22. The control unit 21 comprises a processor 211, a plurality of signal transceivers 212 electrically and respectively connected to the processor 211, and a plurality of trigger devices 213. Each trigger device 213 is respectively provided with a retractable trigger rod 2131. Each sensing device 22 is also provided with a plurality of signal transmitters 221, which can transmit wired or wireless signals with each of the signal transceivers 212.

In practical application of the above components, the isolation space 10 on one side of the frame body 1 is used for installing the driving unit 2. The driving unit 2 utilizes the plurality of sensing devices 22 corresponding to the inner sides of the indicating key surfaces 11 on the other side of the frame body 1 respectively, and the plural trigger devices 213 of the control unit correspond to the other side of each sensing device 22 respectively. The contactless button structure of the present invention can then be constructed by using the frame body 1 and the driving unit 2.

The plurality of indicating key surfaces 11 on the surface of the frame body 1 above includes number keys 111, moving direction keys 112 and a contact mark key 113 respectively marked with a respective symbol.

The plurality of sensing devices 22 of the above-mentioned driving unit 2 can be temperature sensors or infrared sensors, and the control unit 21 can be a circuit board with an electronic circuit layout. The circuit hoard of the control unit 21 can be provided with a power supply for supplying the required electrical energy.

The power supply can be general batteries, lithium batteries, rechargeable batteries, accumulators or commercial power and other types of power sources that can provide electrical energy, Each of the plurality of trigger devices 213 of the driving unit 2 can be motors, pneumatic cylinders, hydraulic cylinders or an electric cylinder. etc., which can drive the retractable trigger rod 2131 to move and retract.

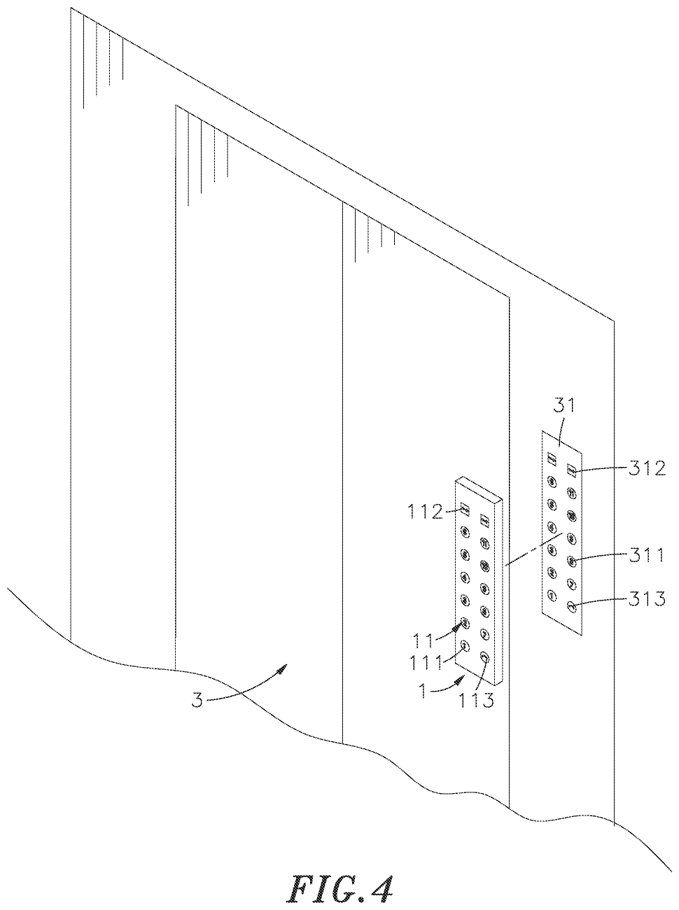

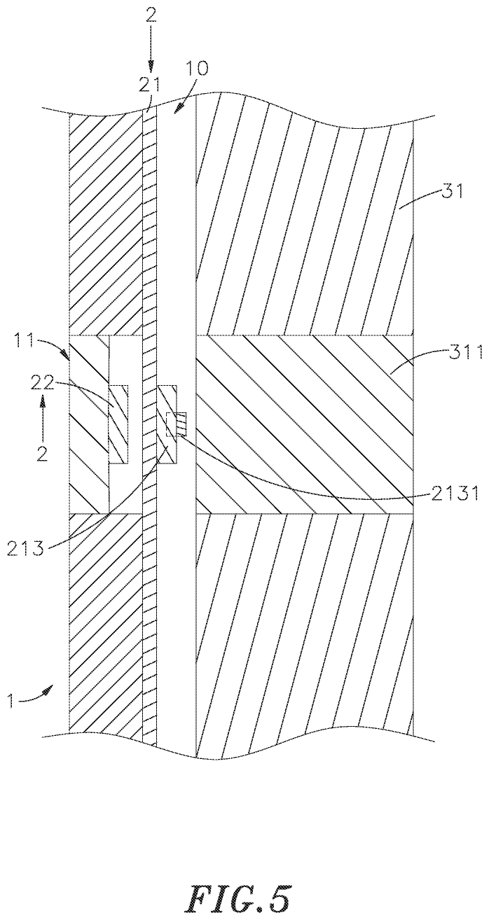

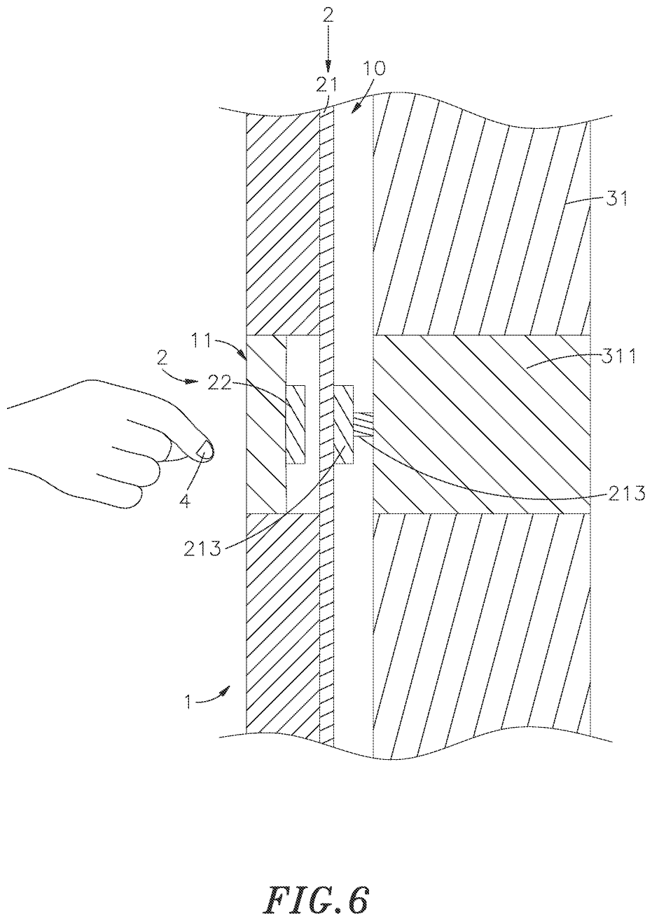

Referring to FIGS. 1-6 as can be clearly seen from the drawings, when the contactless button structure of the present invention is implemented in practical applications, the frame body 1 can be correspondingly installed on the outside of the control key surface 31 of the equipment 3 (such as elevators, access control man-machine interfaces or walkie-talkies, etc.) installed in the building to respectively correspond the number keys 111, moving direction keys 112 and contact mark key 113 of the indicating key surface 11 on one side of the frame body 1 to the respective number buttons 311, moving direction buttons 312, and contact mark button 313 located on the control key surface 31. With respect to the driving unit 2 on the other side of the indicating key surfaces 11, the trigger devices 213 are respectively used to control the number buttons 311, the moving direction buttons 312 and the contact mark buttons 313 in front of the control key surface 31. in this way, the button structure of the present invention is positioned outside the control key surface 31 of the equipment 3. The frame body 1 of the button structure of the present invention can be fixed on the outside of the control key surface 31 by sticking and fixing with an adhesive or fixing with screws.

When the user wants to use the equipment 3, he can move his finger 4 to the indicating key surface 11 of the frame body and use his finger 4 to approach the outside of the number key 111 (or moving direction key 112 or contact mark key 113) of the selected floor, The sensing device 22 of the driving unit 2 on the other side of the indicating key surface 11 detects the finger 4 located outside the indicating key surface 11, that is, transmits the signal to the signal transceiver 212 of the control unit 21 through the signal transmitter 221. Then, the signal transceiver 212 transmits the signal to the processor 211, and the trigger device 213 at the position where the finger 4 is aligned and is controlled by the processor 211. The retractable trigger rod 2131 is driven by the trigger device 213 to extend out and touch the number button 311 (or moving direction button 312 or contact mark buttons 313) of the control key surface 31 at the relative position to achieve the purpose of non-contact operation of the control key surface 31 of the equipment 3. This avoids the actions of unspecified people who use the equipment 3 to touch the control key surface 31, which can effectively reduce the chance of infection and spread of various viruses and bacteria when using the equipment 3. Avoiding the risk of transmission caused by contact can also reduce the chance of contamination of the control key surface 31, which can reduce the number of daily disinfections, and can save time, labor and disinfection costs.

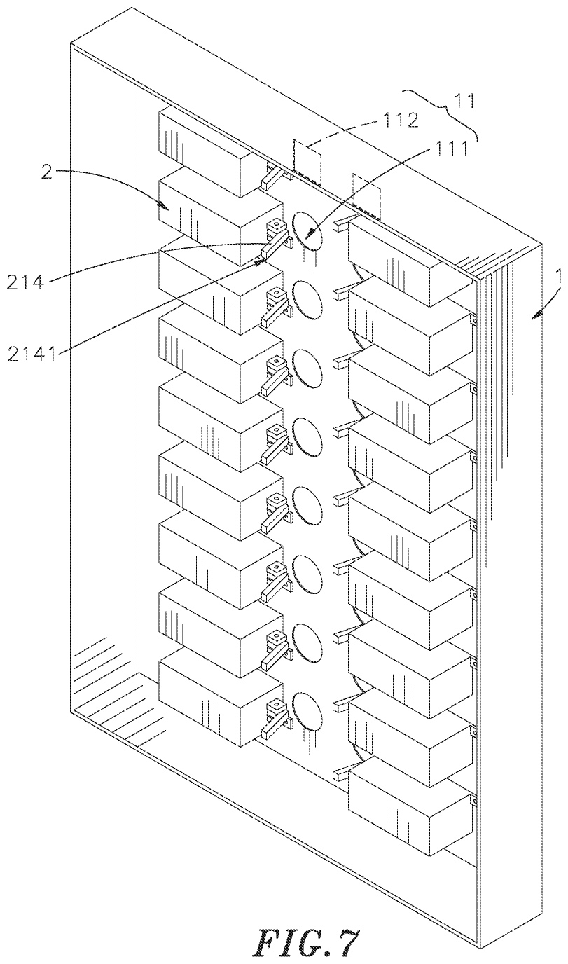

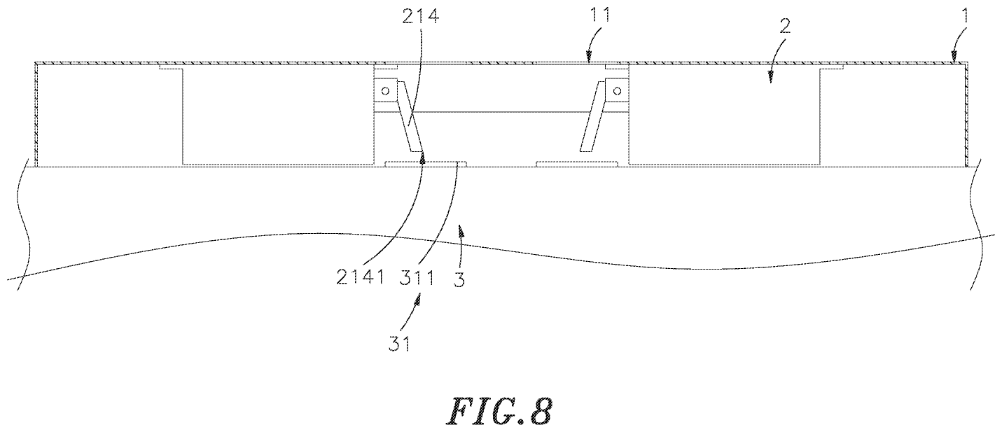

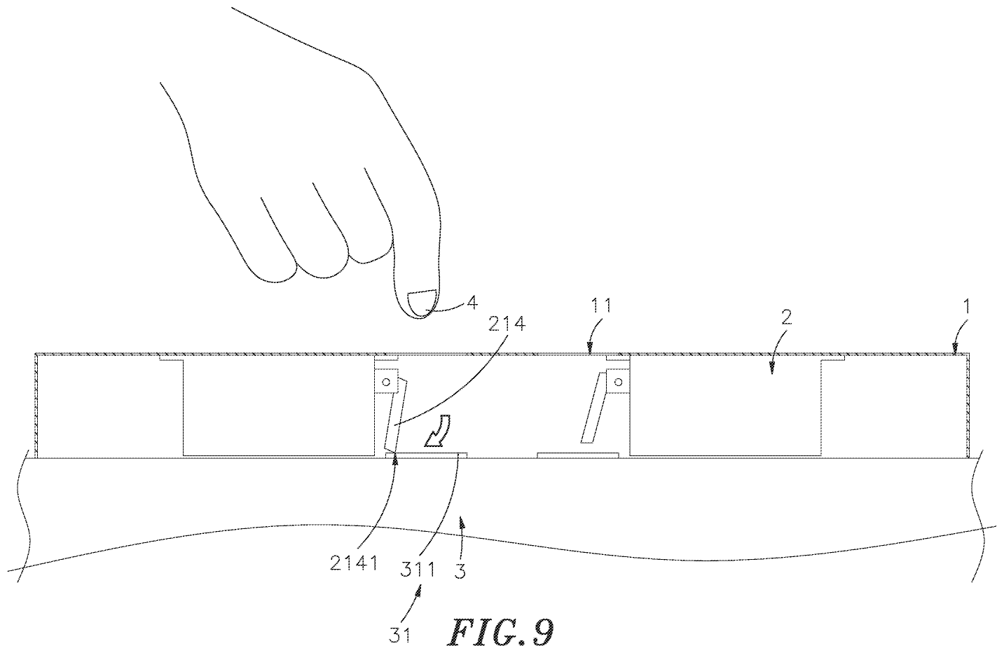

Referring to FIGS. 7-9 and FIGS. 1-4 again, it can be clearly seen from the drawings that in another implemented. embodiment of the contactless button structure of the present invention, the driving unit 2 is respectively provided on the opposite side of the back of each number key 111, each moving direction key 112 and the contact mark key 113 on the indicating key surfaces 11. of the frame body 1. A movable pressing rod 214 is pivoted on one side of each driving unit 2, and each pressing rod. 214 is respectively extended to the back of the respective number key 111, moving direction key 112 and the contact mark key 113, Through the processor 211 of the control unit 21 of each driving unit 2, each pressing rod 214 can be driven to swing and displace in a fan shape.

When the contactless button structure of this implemented embodiment is in practical application, the frame body 1 can be installed outside the control key surface 31 of the equipment 3 installed in the building (such as elevators, access control man-machine interfaces or walkie-talkies, etc.), so that the number keys 111, moving direction keys 112, and contact mark key 113 on the indicating key surfaces 11 of the frame body 1 are respectively aligned with the number buttons 311, moving direction buttons 312 and contact mark button 313 on the control key surface 31. The pressing rods 214 on the one side of each driving unit 2 on the other side of each indicating key surface 11 are respectively positioned on the control key surface 31 at the outer side of the number buttons 311, the moving direction buttons 312 and the contact mark button 313 at appropriate distances. When the user's finger 4 moves to the outside of the indicating key surface 11 of the frame body 1, and uses the finger 4 to approach the outside of the number key 111 (or moving direction key 112 or contact mark key 113) of the selected floor, the sensing device 22 of the driving unit 2 on the other side of the indicating key surface 11 detects the finger 4 located outside the indicating key surface 11, that is, transmits the signal to the signal transceiver 212 of the control unit 21 through the signal transmitter 221. Then the signal transceiver 212 transmits the signal to the processor 211, and the pressing rod 214 at the position where the finger 4 is aligned arid. is controlled by the processor 211, and the pressing rod 214 swings in a fan shape. Thus, the contact end 2141 of the pressing rod 214 touches the number button 311 (or the moving direction button 312 or the contact mark button 313) of the control key surface 31 in the relative position, so as to achieve the purpose of non-contact operation of the control key surface 31 of the equipment 3. This avoids the actions of unspecified people who use the equipment 3 to touch the control key surface 31, which can effectively reduce the chance of infection and spread of various viruses and bacteria when using the equipment 3. Avoiding the risk of transmission caused by contact can also reduce the chance of contamination of the control key surface 31, which can reduce the number of daily disinfections, and can save time, labor and disinfection costs.

What the invention claimed is:

1. A contactless button structure, comprising a frame body and a driving unit, wherein:
said frame body comprises a plurality of indicating key surfaces located on one side thereof and an isolation space located on an opposite side thereof, said isolation space is concavely:,
said driving unit is installed in said isolation space of said frame body, said driving unit comprising a plurality of sensing devices respectively installed on a back side of each said indicating key surface and a control unit that receives an electronic signal of each said sensing device, said control unit comprising a plurality of trigger devices corresponding to said sensing devices respectively, each said trigger device comprising a retractable trigger rod.

2. The contactless button structure as claimed in claim 1, wherein said plural indicating key surfaces of said frame body comprise a plurality of number keys and moving direction keys and a contact mark key respectively marked with a respective symbol.

3. The contactless button structure as claimed in claim 1, wherein said sensing devices of said driving unit are selectively temperature sensors or infrared sensors.

4. The contactless button structure as claimed in claim 1, wherein said control unit of said driving unit is a circuit board with an electronic circuit layout, said control unit comprising a plurality of signal transceivers; said sensing devices respectively comprise a signal transmitter for signal transmission with one respective said signal transceiver.

5. The contactless button structure as claimed in claim 4, wherein the signal transmission between said signal transceivers of said control unit and said signal transmitters of said sensing devices is selectively carried out by wired or wireless means.

6. The con tactless button structure as claimed in claim 1, wherein each said trigger device of said driving unit is selectively a motor, a pneumatic cylinder, a hydraulic cylinder or an electric cylinder.
